(19) United States
(12) Patent Application Publication
(10) Pub. No.: US 2009/0032916 A1
(43) Pub. Date: Feb. 5, 2009

(54) SEMICONDUCTOR PACKAGE APPARATUS

(75) Inventors: Dong-Kil SHIN, Gyeonggi-do (KR); Sang-Wook PARK, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/182,843

(22) Filed: Jul. 30, 2008

(30) Foreign Application Priority Data
Aug. 2, 2007 (KR) 2007-0077808

(51) Int. Cl. H01L 23/495

(52) U.S. Cl. 257/666; 257/E23.031

(57) ABSTRACT

A semiconductor package apparatus and a method of fabricating the semiconductor package apparatus. The semiconductor package apparatus includes: semiconductor chips comprising active and inactive surfaces and protected by a packing portion; a substrate on which the semiconductor chips are installed; leads comprising front portions electrically coupled to the active surfaces of the semiconductor chips and rear portions extending substantially to the substrate; and bonding materials bonded between ends of the rear portions of the leads and the substrate to electrically couple the leads to the substrate. Ends of the rear portions of the leads may stand on the substrate. Thus, solder joint reliability can be improved, and a wetting characteristic of solder can be improved during surface installation. Also, semiconductor package apparatuses having similar attributes can easily be multilayered. In addition, a foot print of the semiconductor package apparatus can be reduced to enable high-density installation. Moreover, shapes of the bonding materials (solder) can be controlled to optimize bonding strength of the leads, quantity of the bonding materials, or the like.

### CROSS-REFERENCE TO RELATED PATENT APPLICATION

This application claims the benefit of Korean Patent Application No. 10-2007-0077808, filed on Aug. 2, 2007, in the Korean Intellectual Property Office, the disclosure of which is incorporated herein in its entirety by reference.

### BACKGROUND OF THE INVENTION

1. Field of the Invention

The present invention relates to a semiconductor package apparatus and a method of fabricating the same, and more particularly, to a semiconductor package apparatus for improving reliability of a joint and a method of fabricating the same.

2. Description of the Related Art

In general, packaging processes are used to seal semiconductor chips having designed micro-circuits using a sealing material such as plastic resin, a ceramic material, or the like to install the semiconductor chips on a real electronic device. Thus, such packaging processes are very important to make semiconductors and electronic devices into final products.

A semiconductor package apparatus fabricated using such packaging processes can protect semiconductor chips from outer environments. The semiconductor package apparatus should connect the semiconductor chips to parts of the semiconductor package apparatus and smoothly emit heat generated during operations of the semiconductor chips in order to secure reliability of thermal and electrical performances of the semiconductor chips.

### SUMMARY OF THE INVENTION

The present invention provides a semiconductor package apparatus for improving solder joint reliability under a thermal cycling environment in which semiconductor chips operate, improving a wetting characteristic of solder during surface installation, allowing semiconductor package apparatuses complying with the same standards to be easily multilayered, and reducing a foot print of the semiconductor package apparatus to enable high-density installation, and a method of fabricating the semiconductor package apparatus.

According to an aspect of the present invention, there is provided a semiconductor package apparatus which may include: semiconductor chips comprising active and inactive surfaces and protected by a packing portion; a substrate on which the semiconductor chips are installed; leads comprising front portions electrically coupled to the active surfaces of the semiconductor chips and rear portions extending substantially to the substrate; and bonding materials bonded between ends of the rear portions of the leads and the substrate to electrically couple the leads to the substrate. The ends of the rear portions of the leads may stand on the substrate.

The semiconductor package apparatus may be an exposed lead frame package type apparatus so that the leads are inverted above the substrate to expose at least some of the front portions of the leads to the outside.

The semiconductor package apparatus may further include a die pad comprising a surface on which the semiconductor chips are installed so that the active surfaces face the substrate, the die pad being exposed above the packing portion.

The semiconductor chips may have a stack structure in which a plurality of chips are multilayered.

The semiconductor chips may be electrically coupled to the leads using wires. The packing portion may be formed of a resin sealing material to enclose sides of the semiconductor chips and the wires.

The rear portions of the leads may form a stack inclination angle so that when a plurality of semiconductor package apparatuses are stacked, rear portions of leads of an upper semiconductor package apparatus are bonded to rear portions of leads of a lower semiconductor package apparatus without interference between the rear portions of the leads of the upper and lower semiconductor package apparatuses.

The rear portions of the leads may have step differences.

The semiconductor package apparatus may further include interlayer bonding materials bonded between joints of leads of upper and lower semiconductor package apparatuses to electrically couple the joints of the leads of the upper semiconductor package apparatus to the joints of the leads of the lower semiconductor package apparatus when a plurality of semiconductor package apparatuses are stacked in N layers.

The bonding materials may protrude upward to have long semi-elliptical cross-sections so that foot prints of the bonding materials are flat to contact circuit layers of the substrate, and upper surfaces of the bonding materials enclose the joints of the leads.

Left and right shapes of the cross-sections of the bonding materials may depend on relative positions of the circuit layers exposed by a removal of a solder resist so that more of the bonding materials are bonded to one side of the rear portions of the leads than to another side of the rear portions of the leads.

The joints of the leads may include surface treating portions to improve bonding strength.

The surface treating portions may be formed by gold coating.

Uneven portions may be treated to form the surface treating portions.

Heights of the bonding materials may be determined by lengths of the surface treating portions of the joints.

Flexible portions may be formed at an upper part of the rear portions of the leads, the flexible portions having a reduced thickness respective to a lower part of the rear portions, thereby increasing flexibility of the leads so as to relieve impacts or stress transmitted to the bonding materials.

At least one bending portions may be formed at the rear portions of the leads at a predetermined bending angle.

Reinforcement portions may be formed at the lower part of the rear portions of the leads having a reinforced thickness greater than the thickness of the flexible portions, thereby increasing rigidity and bonding strength.

Facing portions may be formed on the circuit layers on the substrate so that the circuit layers engage with joints of the leads.

According to another aspect of the present invention, there is provided a method of fabricating a semiconductor package apparatus, including: providing semiconductor chips including active and inactive surfaces and protected by a packing portion; installing the semiconductor chips on a substrate; providing bonding materials on the substrate; providing leads including front portions electrically coupled to the active surfaces of the semiconductor chips and rear portions extending to the substrate; bonding bonding materials between the leads and the substrate to electrically couple the leads to the substrate and standing portions of the leads on the substrate, wherein the leads include ends electrically coupled to the bonding materials; and adjusting relative positions of circuit layers of the substrate exposed by a removal of a solder resist, based on the leads to determine left and right shapes of cross-sections of the bonding materials.

According to another aspect of the present invention, there is provided a method of fabricating a semiconductor package apparatus, including: providing semiconductor chips including active and inactive surfaces and protected by a packing portion; installing the semiconductor chips on a substrate; providing bonding materials on the substrate; providing leads including front portions electrically coupled to the active surfaces of the semiconductor chips and rear portions extending to the substrate; bonding bonding materials between the leads and the substrate to electrically couple the leads to the substrate and standing portions of the leads on the substrate, wherein the leads include ends electrically coupled to the bonding materials; and surface-treating joints of the leads to improve bonding strength and adjusting lengths of the surface-treated joints to determine heights of the bonding materials.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a semiconductor package apparatus according to a preferred embodiment of the present invention;

FIG. 2 is an enlarged cross-sectional view of a portion of the semiconductor package apparatus of FIG. 1;

FIG. 3 is the enlarged view of FIG. 2 illustrating a state in which stress operates;

FIG. 4 is an enlarged cross-sectional view of a portion of a semiconductor package apparatus according to another preferred embodiment of the present invention;

FIG. 5 is an enlarged cross-sectional view of the portion of the semiconductor package apparatus of FIG. 4, according to another preferred embodiment of the present invention;

FIG. 6 is an enlarged cross-sectional view of the portion of the semiconductor package apparatus of FIG. 4, according to another preferred embodiment of the present invention;

FIG. 7 is a cross-sectional view of stacked semiconductor package apparatuses according to a preferred embodiment of the present invention;

FIG. 8 is an enlarged cross-sectional view of a portion of a semiconductor package apparatus according to another preferred embodiment of the present invention;

FIG. 9 is an enlarged cross-sectional view of the portion of the semiconductor package apparatus of FIG. 8, according to another preferred embodiment of the present invention;

FIG. 10 is an enlarged cross-sectional view of a portion of a semiconductor package apparatus according to another preferred embodiment of the present invention;

FIG. 11 is an enlarged cross-sectional view of a portion of a semiconductor package apparatus according to another preferred embodiment of the present invention;

FIG. 12 is an enlarged cross-sectional view of a portion of a semiconductor package apparatus according to another preferred embodiment of the present invention;

FIG. 13 is an enlarged cross-sectional view of a portion of a semiconductor package apparatus according to another preferred embodiment of the present invention; and

FIG. 14 is a cross-sectional view of a portion of stacked semiconductor package apparatuses according to a preferred embodiment of the present invention;

### DETAILED DESCRIPTION OF THE INVENTION

Semiconductor package apparatuses and a method of fabricating the semiconductor package apparatuses according to preferred embodiments of the present invention will now be described in detail with reference to the attached drawings.

As shown in FIG. 1, a semiconductor package apparatus 10 according to a preferred embodiment of the present invention includes semiconductor chips 2 that are protected by a packing portion 1, a substrate 3 on which the semiconductor chips 2 are installed, leads 7, and bonding materials 8.

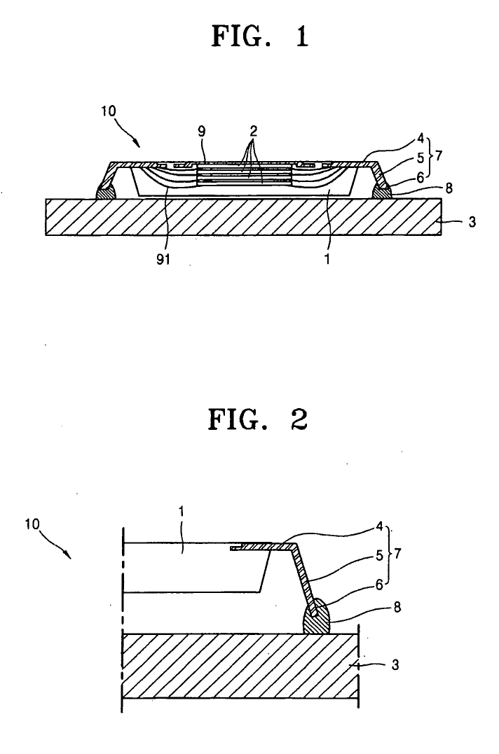

As shown in FIG. 2, the leads 7 include front portions 4 that are electrically coupled to the semiconductor chips 2 and rear portions 5 that extend to the substrate 3. Also, portions of the leads 7 may be co-axially aligned with one another to form a “1” shape on the substrate 3—e.g. the rear portions 5 and their end portions/joints 6 bonded to the substrate by bonding material 8. Furthermore, these rear portions 5 and co-axial joints 6 may be coupled together with a front portion 4 to form an obtuse angle opening toward the packing portion 1 on the substrate 3.

As shown in FIG. 1, the semiconductor package apparatus may be of an exposed lead frame package type so that the leads 7 are inverted on the substrate 3 to expose the front portions 4 to the outside. In the semiconductor package apparatus 10 fabricated as the exposed lead frame package type, a surface of a die pad 9 on which the semiconductor chips 2 are placed may be exposed upward. Here, the semiconductor chips 2 have active and inactive surfaces and may be installed on the die pad 9 so that the active surfaces face the substrate 3.

The bonding materials 8 are bonded between the substrate 3 and the joints 6 of the leads 7 to electrically couple the joints 6 of the leads 7 to the substrate 3. The bonding materials 8 may be solder or various types of welding materials such as gold, silver, aluminum, etc. that enable electrical connections and solid fixations. The semiconductor chips 2 may have a stack structure in which a plurality of semiconductor chips 2 are multilayered, and may be electrically coupled to the leads 7 through various types of signal transmitter such as wires 91, etc. The packing portion 1 may be formed of a resin sealing material or a ceramic material so as to enclose sides of the semiconductor chips 2 and the wires 91.

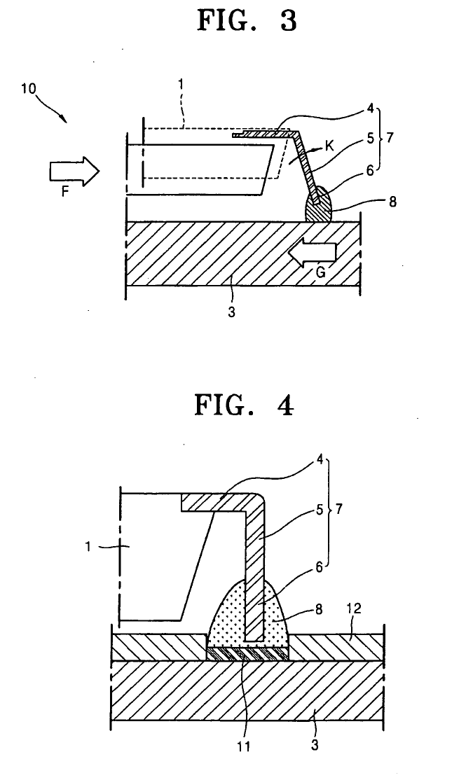

Therefore, the semiconductor package apparatus 10 of the present preferred embodiment includes the leads 7 that have the front portions 4, the rear portions 5, and the joints 6, as shown in FIG. 2. In particular, the joints 6 of the rear portions 5 contact the bonding materials 8 and stand on the substrate 3. Thus, as shown in FIG. 3, if thermal stress F is generated under a thermal cycling environment formed by operations of the semiconductor chips 2 to generate a repulsive force G in the substrate 3 so as to apply stress to the leads 7, lead stress K is generated in the leads 7 that have the rear portions 5 with the joints 6 formed in the “1” shapes. In other words, the leads 7 standing in the “1” shapes operate as levers due to the thermal stress F to be easily and elastically deformed by the lead stress K so as to absorb or intercept stress or impacts. As a result, the bonding materials 8 or the substrate 3 that are relatively weak are prevented from being damaged or broken down. In particular, the leads 7 improve solder joint reliability of the joints 6 and improve a solder wetting characteristic during surface installation.

As shown in FIG. 4, the bonding materials 8 may protrude upward. Thus, the bonding materials 8 may have long semi-elliptical cross-sections so that foot prints of the bonding materials 8 are flat so as to contact circuit layers 11 of the substrate 3. Upper surfaces of the bonding materials 8 enclose the joints 6 of the leads 7. Although not shown, besides the long semi-elliptical cross-sections, the bonding materials 8 may have various shapes of cross-sections including circular, triangular, tetragonal, polygonal, and irregular cross-sections, etc.

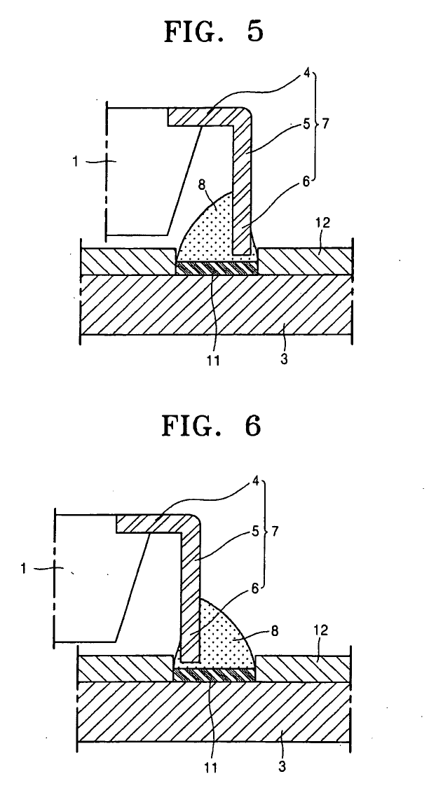

In particular, as shown in FIGS. 5 and 6, left and right shapes of the cross-sections of the bonding materials 8 may depend on relative positions of the circuit layers 11 that have been exposed by a removal of a solder resist 12, based on the leads 7. In other words, as shown in FIG. 5, positions of the exposed circuit layers 11 may be adjusted inside the leads 7, such that the bonding materials 8 form a left shape to reinforce the bonding materials 8 inside the leads 7, thereby minimizing a foot print of the semiconductor package apparatus 10. As shown in FIG. 6, the positions of the exposed circuit layers 11 may be adjusted outside the leads 7, such that the bonding materials 8 form a right shape to reinforce the bonding materials 8 outside the leads 7, thereby firmly fixing the leads 7. As shown in FIGS. 5 and 6, more of the bonding materials 8 may be bonded to one side of the leads 7 than to another side of the leads 7.

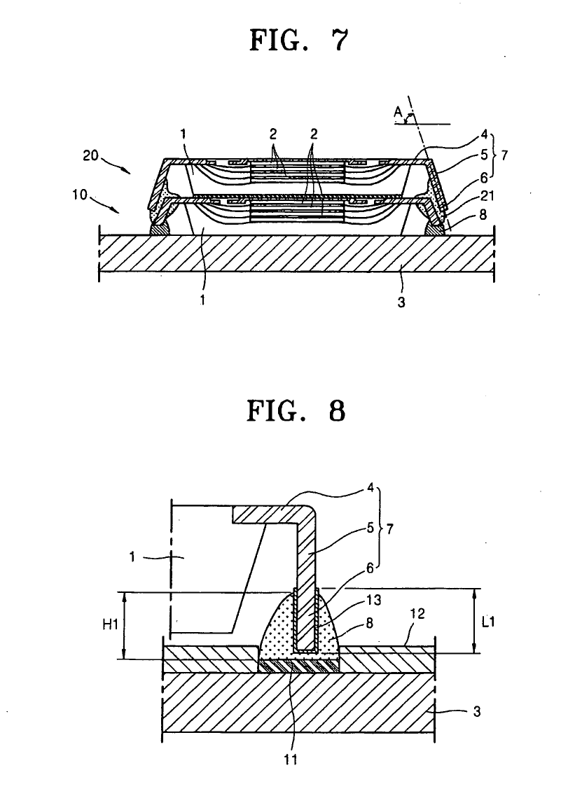

As shown in FIG. 7, a plurality of semiconductor packages 10 and 20 may overlap with one another such that they are stacked. Here, the rear portions 5 of the leads 7 may form a stack inclination angle A so that the leads 7 of the upper semiconductor package apparatus 20 are bonded to the leads 7 of the lower semiconductor package apparatus 10 without interference between the rear portions 5 of the leads 7 of the upper and lower semiconductor package apparatuses 20 and 10.

If the semiconductor package apparatuses 10 and 20 are stacked in two or more layers, interlayer bonding materials 21 may be bonded between the joints 6 of the leads 7 of the upper semiconductor package apparatus 20 and the joints 6 of the leads 7 of the lower semiconductor package apparatus 10. Thus, the joints 6 of the leads 7 of the upper semiconductor package apparatus 20 may be electrically coupled to the joints 6 of the leads 7 of the lower semiconductor package apparatus 10 through the interlayer bonding materials 21.

The interlayer bonding materials 21 function to electrically couple the leads 7 of the upper semiconductor package apparatus 20 to the leads 7 of the lower semiconductor package apparatus 10 and firmly fix the upper semiconductor package apparatus 20 to the lower semiconductor package apparatus 10. The interlayer bonding materials 21 may be formed of solder enabling electrical connections and firm fixations or welding materials such as gold, silver, copper, aluminum, or the like.

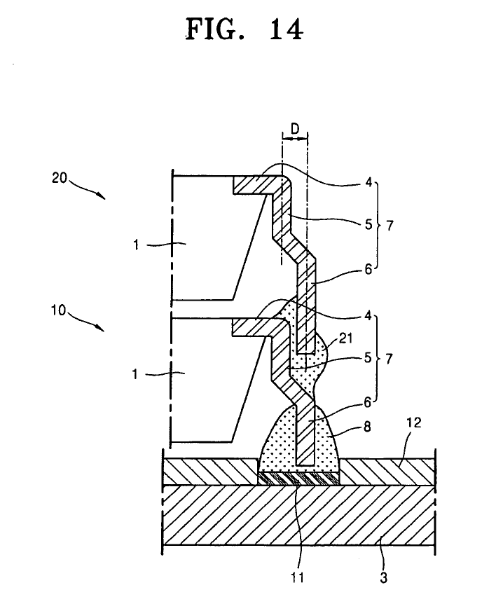

Also, referring forward to FIG. 14, the rear portions 5 of the leads 7 may have step differences D so that when the plurality of semiconductor package apparatuses 10 and 20 are stacked, the leads 7 of the upper semiconductor package apparatus 20 are bonded to the leads 7 of the lower semiconductor package apparatus 10 without interference between the rear portions 5 of the leads 7 of the upper and lower semiconductor package apparatus 20 and 10.

Even in this case, the interlayer bonding materials 21 are bonded between the joints 6 of the upper and lower semiconductor package apparatuses 20 and 10 so as to enable the electrical connection between the leads 7 of the upper and lower semiconductor package apparatuses 20 and 10, and to provide a firm fixation of the upper semiconductor package apparatus 20 to the lower semiconductor package apparatus 10.

Accordingly, the semiconductor package apparatuses 10 and 20 are more easily layered in a multilayer fashion (i.e., the semiconductor package apparatuses may be stacked in two or more layers). As a result, high-density installation of the semiconductor package apparatuses can be achieved.

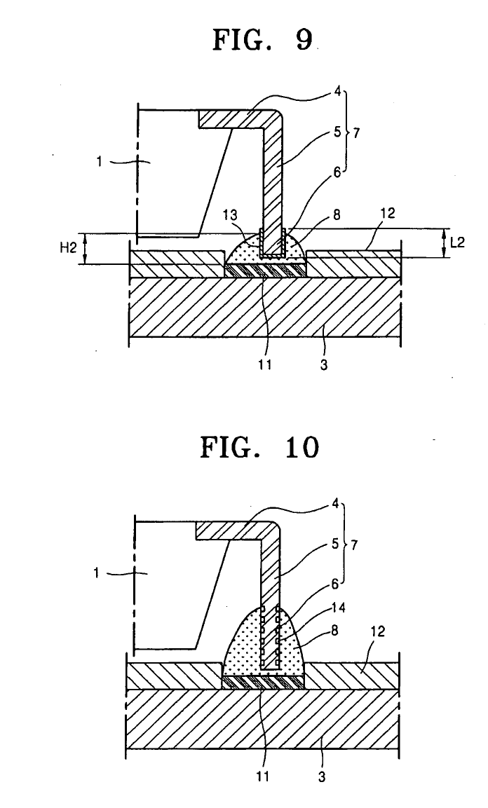

Referring now to FIGS. 8 and 9, surface treating portions 13 may be formed on the joints 6 of the leads 7 to improve bonding strength. The surface treating portions 13 may be formed by gold coating having good conductivity and solder wetting characteristic. In particular, as shown in FIGS. 8 and 9, heights H1 and H2 of the bonding materials 8 may be determined by lengths L1 and L2 of the surface treating portions 13 of the joints 6.

For example, as shown in FIG. 8, the length L1 of the surface treating portions 13 may extend to increase the height H1 of the bonding materials 8 so as to enable a firmer fixation. As shown in FIG. 9, the length L2 of the surface treating portions 13 may be shortened to lower the height H2 of the bonding materials 8 so as to save a needed amount of the bonding materials 8.

Referring to FIG. 10, various types of uneven portions 14 such as holes, grooves, or projections may be treated to form the surface treating portions 13 so as to improve bonding strength between the surface treating portions 13 and the bonding materials 8. As a result, the bonding materials 8 penetrate into the uneven portions 14 to greatly increase the bonding strength so as to firmly fix even more the leads 7 to the circuit layers 11.

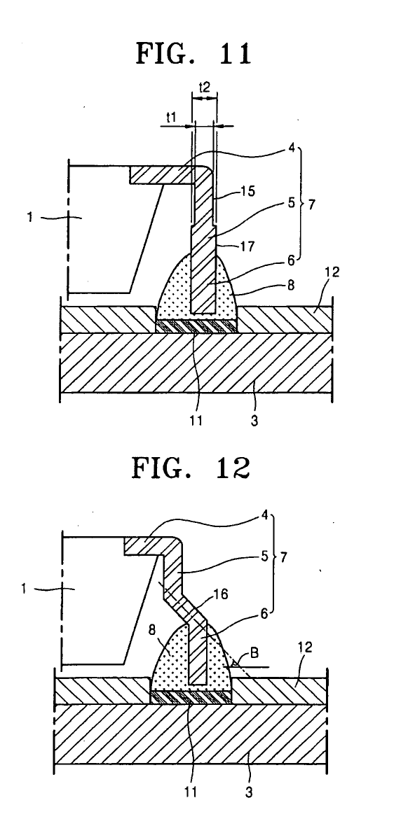

As shown in FIG. 11, flexible portions 15 may be formed at an upper part of the rear portions 5 of the leads 7. The flexible portions 15 may have a reduced thickness t1 (or reduced width). The reduced thickness t1 may be less than the thickness of the respective joints 6 of the leads 7. Thus, the flexible portions 15 may increase flexibility of the leads 7 so as to relieve impacts or stress transmitted to the bonding materials 8.

Also, as shown in FIG. 11, reinforcement portions 17 may be formed at a lower part of the rear portions 5 and joints 6 of the leads 7. The reinforcement portions 17 may have a reinforced thicknesses t2 (or reinforced width). The reinforced thickness t2 may be more than the thickness of the respective flexible portions 15. As a result, the reinforcement portions 17 may increase rigidity of the joints 6 so as to improve the bonding strength with the bonding materials 8.

Accordingly, in the semiconductor package apparatus of the embodiment illustrated in FIG. 11, the flexible portions 15 can increase flexibility so as to greatly relieve repeated impacts or stress applied due to thermal stress or the like. Also, the reinforcement portions 17 can increase the bonding strength so as to prevent parts of the semiconductor package apparatus from being damaged or broken down.

Referring to FIG. 12, instead of the flexible portions 15 of FIG. 11, bending portions 16 may be formed at a bending angle B to increase the flexibility of the leads 7 so as to relieve the impacts or stress transmitted to the bonding materials 8. In this embodiment, the rear portion 5 and joint portion 6 are no longer co-axial.

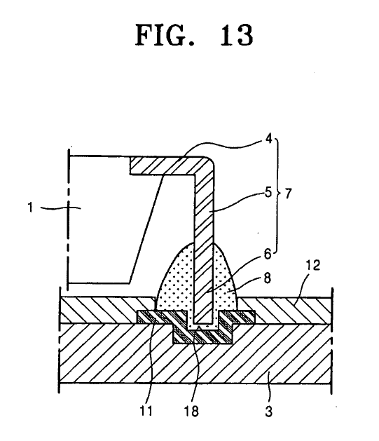

Referring to FIG. 13, facing portions 18 may be formed at the circuit layers 11 formed on the substrate 3 so that the circuit layers 11 engage with the joints 6 of the leads 7. In other words, the joints 6 of the leads 7 engage with the facing portions 18 of the circuit layers 11, and then the bonding materials 8 are bonded to the leads 7. Thus, the leads 7 can be firmly fixed even more to prevent the parts of the semiconductor package from being damaged or broken down.

A method of fabricating a semiconductor package apparatus according to a preferred embodiment of the present invention will now be described.

As shown in FIGS. 5 and 6, the semiconductor chips 2 are installed on the substrate 3 and are protected by the packing portion 1, all of which comprise the semiconductor package apparatus. Next the bonding materials 8 may be bonded onto the substrate 3. Thereafter, portions of the leads 7 are inserted into the bonding materials 8 to stand on the substrate 3. The relative positions of the circuit layers 11 of the substrate 3 exposed by the removal of the solder resist 12 are adjusted based on the leads 7 to determine the left and right shapes of the cross-sections of the bonding materials 8. As shown in FIGS. 8 and 9, the joints 6 of the leads 7 are surface-treated to improve the bonding strength of the bonding materials 8. The lengths L1 and L2 of the joints 6 are adjusted to determine the heights H1 and H2 of the bonding materials 8.

Accordingly, in the present invention, the bonding materials 8 may be bonded in desired shapes appropriately using various methods. Thus, a shape of solder can be smoothly controlled to optimize the bonding strength of the leads 7, the needed amount of the bonding materials 8, or the like.

As described above, in a semiconductor package apparatus and a method of fabricating the semiconductor package apparatus according to the present invention, solder joint reliability can be improved under a thermal cycling environment. Also, a wetting characteristic of solder can be improved during surface installation, and semiconductor package apparatuses complying with the same standards can be multilayered more easily. In addition, a foot print of the semiconductor package apparatus can be reduced so as to enable high-density installation. Moreover, shapes of bonding materials (solder) can be controlled to optimize bonding strength of leads, a quantity of the bonding materials, or the like.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package apparatus comprising:
semiconductor chips comprising active and inactive surfaces and protected by a packing portion;
a substrate on which the semiconductor chips are installed;
leads comprising front portions electrically coupled to the active surfaces of the semiconductor chips and rear portions extending substantially to the substrate; and
bonding materials bonded between ends of the rear portions of the leads and the substrate to electrically couple the leads to the substrate,
wherein the ends of the rear portions of the leads stand on the substrate.

2. The semiconductor package apparatus of claim 1, wherein the semiconductor package apparatus is an exposed lead frame package type apparatus so that the leads are inverted above the substrate to expose at least some of the front portions of the leads to the outside.

3. The semiconductor package apparatus of claim 1, further comprising a die pad comprising a surface on which the semiconductor chips are installed so that the active surfaces face the substrate, the die pad being exposed above the packing portion.

4. The semiconductor package apparatus of claim 1, wherein the semiconductor chips have a stack structure in which a plurality of chips are multilayered.

5. The semiconductor package apparatus of claim 1, wherein the semiconductor chips are electrically coupled to the leads using wires.

6. The semiconductor package apparatus of claim 5, wherein the packing portion is formed of a resin sealing material to enclose sides of the semiconductor chips and the wires.

7. The semiconductor package apparatus of claim 1, wherein the rear portions of the leads form a stack inclination angle so that when a plurality of semiconductor package apparatuses are stacked, rear portions of leads of an upper semiconductor package apparatus are bonded to rear portions of leads of a lower semiconductor package apparatus without interference between the rear portions of the leads of the upper and lower semiconductor package apparatuses.

8. The semiconductor package apparatus of claim 1, wherein the rear portions of the leads have step differences.

9. The semiconductor package apparatus of claim 1, further comprising interlayer bonding materials bonded between joints of leads of upper and lower semiconductor package apparatuses to electrically couple the joints of the leads of the upper semiconductor package apparatus to the joints of the leads of the lower semiconductor package apparatus when a plurality of semiconductor package apparatuses are stacked in N layers.

10. The semiconductor package apparatus of claim 1, wherein the joints of the leads comprise surface treating portions to improve bonding strength.

11. The semiconductor package apparatus of claim 10, wherein the surface treating portions are formed by gold coating.

12. The semiconductor package apparatus of claim 10, wherein uneven portions of the joints are treated to form the surface treating portions.

13. The semiconductor package apparatus of claim 10, wherein heights of the bonding materials are determined by lengths of the surface treating portions of the joints.

14. The semiconductor package apparatus of claim 1, further comprising flexible portions formed at an upper part of the rear portions of the leads, the flexible portions having a reduced thickness respective to a lower part of the rear portions, thereby increasing flexibility of the leads so as to relieve impacts or stress transmitted to the bonding materials.

15. The semiconductor package apparatus of claim 1, further comprising at least one bending portion formed at the rear portions of the leads at a predetermined bending angle.

16. The semiconductor package apparatus of claim 14, further comprising reinforcement portions formed at the lower part of the rear portions of the leads having a reinforced thickness greater than the thickness of the flexible portions, thereby increasing rigidity and bonding strength.

17. The semiconductor package apparatus of claim 1, further comprising facing portions formed on the circuit layers on the substrate so that the circuit layers engage with joints of the leads.

18. A semiconductor package apparatus comprising:
semiconductor chips comprising active and inactive surfaces and protected by a packing portion;
a substrate on which the semiconductor chips are installed;
leads comprising front portions electrically coupled to the active surfaces of the semiconductor chips and rear portions extending substantially to the substrate; and
bonding materials bonded between ends of the rear portions of the leads and the substrate to electrically couple the leads to the substrate,
wherein the bonding materials protrude upward to have semi-elliptical cross-sections so that foot prints of the bonding materials are flat to contact circuit layers of the substrate, and wherein upper surfaces of the bonding materials enclose joints of the leads.

19. The semiconductor package apparatus of claim 10, wherein left and right shapes of the cross-sections of the bonding materials depend on relative positions of the circuit layers exposed by a removal of a solder resist so that more of the bonding materials are bonded to one side of the rear portions of the leads than to another side of the rear portions of the leads.

20. A semiconductor package apparatus comprising:
a substrate;
a first semiconductor package apparatus, comprising:
semiconductor chips comprising active and inactive surfaces and protected by a packing portion;
leads comprising front portions electrically coupled to the active surfaces of the semiconductor chips and rear portions extending substantially to the substrate;
a second semiconductor package apparatus, comprising:
semiconductor chips comprising active and inactive surfaces and protected by a packing portion;
leads comprising front portions electrically coupled to the active surfaces of the semiconductor chips and rear portions extending substantially to the rear portions of the leads of the first semiconductor package apparatus; and
bonding materials bonded between ends of the rear portions of the leads of the first and second semiconductor package apparatuses and the substrate to electrically couple the leads to the substrate,
wherein the rear portions of the leads of the first and second semiconductor package apparatuses have step differences so that the rear portions of leads of the second semiconductor package apparatus are bonded to the rear portions of leads of the first semiconductor package apparatus without interference between the rear portions of the leads of the first and second semiconductor package apparatuses.
